(19) United States
(12) Patent Application Publication
(10) Pub. No.: US 2026/0039294 A1
(43) Pub. Date: Feb. 5, 2026

(54) HIGH-FREQUENCY PRESS-PACK SIC FIELD EFFECT TRANSISTOR (FET) MODULES

(71) Applicant: NUtech Ventures, Lincoln, NE (US)

(72) Inventors: Jun Wang, Lincoln, NE (US); Ekaterina Muravleva, Lincoln, NE (US); Bogac Canbaz, Lincoln, NE (US); Liyan Qu, Lincoln, NE (US)

(21) Appl. No.: 19/350,931

(22) Filed: Oct. 6, 2025

Related U.S. Application Data
(63) Continuation of application No. PCT/US2024/025165, filed on Apr. 18, 2024.
(60) Provisional application No. 63/496,779, filed on Apr. 18, 2023.

(51) Int. Cl. H03K 17/687; H03K 17/567; H03K 17/60

(52) U.S. Cl. CPC H03K 17/6871; H03K 17/567; H03K 17/60

(57) ABSTRACT

A power module is provided, which includes a plurality of switch cells having one or more different switch position topologies, and a plurality of spaces, each space of the plurality of spaces located between two adjacent switch cells among the plurality of switch cells, wherein the plurality of spaces are configured to accommodate one or more decoupling capacitor assemblies. The converter module also includes a plurality of first electrodes, each first electrode of the plurality of first electrodes connected to a top surface of a particular switch cell among the plurality of switch cells, a plurality of second electrodes, each second electrode of the plurality of second electrodes connected to a bottom surface of a particular switch cell among the plurality of switch cells, and a control circuit electrically connected to the plurality of switch cells.

### CROSS REFERENCE TO RELATED APPLICATION

This Patent Application is a continuation of International Application No. PCT/US2024/025165, filed Apr. 18, 2024, which claims priority to U.S. Provisional Patent Application No. 63/496,779, entitled “HIGH-FREQUENCY PRESS-PACK SIC FIELD EFFECT TRANSISTOR (FET) MODULES”, filed Apr. 18, 2023, which are both incorporated herein by reference in their entireties.

### FIELD

The present disclosure relates to circuit protection technologies, and more specifically to power protection modules including novel modularity and stacking arrangements of high-frequency press-pack (HFPP) cells exhibiting low power-loop inductance.

### BACKGROUND

Emerging medium-voltage (MV) distribution-grid-scale power converters are seeking high-current, low-conduction-loss, and high-switching-speed power modules for higher distribution efficiency and reinforced grid resilience. Meanwhile, short-circuit failure modes (SCFM) are also necessary for series redundancy when the converter voltage is scaled up. Power modules with similar features for the conventional distribution grid are silicon (Si) press-pack (PP) silicon controlled rectifiers (SCRs), integrated gate-commutated thyristors (IGCTs), and insulated-gate bipolar transistors (IGBTs). However, these conventional power modules are subjected to inevitable forward voltage drop during conduction and limited turn-off current or switching frequency during switching. High-frequency press-pack (HFPP) silicon carbide (SiC) field effect transistor (FET) modules that incorporate a substantial number of SiC FET dies in a single package can serve as a viable one-stop solution to address these issues. Despite the similarity of SiC FETs and Si IGBTs, existing PP IGBT module packaging techniques do not apply to SiC FETs. For example, the state-of-the-art PP IGBT stacks feature high power-loop inductance for multilevel topologies, which is acceptable for low-speed Si IGBTs but intolerable for SiC FETs that can switch much faster, e.g., 10 times faster. Moreover, the size of SiC FET dies and pads is 50%-80% smaller than IGBT chips, making the press-contact to the source and gate pads using conventional technologies nearly impossible. One SiC MOSFET module design has been prototyped, in which fuzz buttons are used for die press-contact. However, fuzz buttons have low current ampacity, high stray inductance, and high resistance; they also lack SCFM due to insufficient contact stress.

Accordingly, there is a need for addressing these and other issues associated with the prior art technologies.

### SUMMARY

The systems and methods according to the present embodiments provide novel modularity and stacking arrangements of high-frequency press-pack (HFPP) cells for low power-loop inductance.

To address the power-loop inductance and packaging challenges for HFPP SiC FET modules, the present disclosure provides a configurable modularity and a “dc”-to-“ac” stacking concept, as opposed to the conventional fixed modularity and “dc+”-to-“dc−” stacking; and a novel HFPP cell design and packaging approach. In certain embodiments, the cell design and packaging approach includes double-sided sintering of silicon carbide (SiC) FET dies, a multi- (e.g., four-) leg monolithic spring (MS) to maintain the SCFM, and low-parasitics gate-loop interconnection for many parallel SiC dies.

According to an embodiment, a converter module is provided. The converter module includes a first direct current (DC) node, a second DC node, and a switching node having a voltage potential that is jumping or varying, e.g., AC. The converter module further includes a first power module comprising a plurality of first switch cells, the plurality of first switch cells having one of one or more different switch position topologies; and a second power module comprising a plurality of second switch cells, the plurality of second switch cells having one of the one or more different switch position topologies, wherein the first power module has a top surface electrically connected to a bottom surface of the second power module, whereby one or more first switch cells are connected to one or more of the plurality of second switch cells in the second power module, wherein the first power module is electrically connected to the first DC node and the second DC node via contacts on a bottom surface of the first power module, and wherein the second power module is electrically connected to the AC node via one or more contacts on a top surface of the second power module. In certain aspects, the converter module is a three-level or a five-level neutral point clamped (NPC) inverter. In certain aspects, the one or more switch devices comprises at least one of a diode, a bipolar transistor, a bipolar junction transistor (BJT), or a field effect transistor (FET).

According to an embodiment, a power module is provided that includes a plurality of switch cells having one or more different switch position topologies, and a plurality of spaces, each space of the plurality of spaces located between two adjacent switch cells among the plurality of switch cells, wherein the plurality of spaces are configured to accommodate one or more decoupling capacitor assemblies. The converter module also includes a plurality of first electrodes, each first electrode of the plurality of first electrodes connected to a top surface of a particular switch cell among the plurality of switch cells, a plurality of second electrodes, each second electrode of the plurality of second electrodes connected to a bottom surface of a particular switch cell among the plurality of switch cells, and a control circuit electrically connected to the plurality of switch cells.

In certain aspects, each switch cell among the plurality of switch cells comprises a plurality of parallel paths, and each path among the plurality of parallel paths in a respective switch cell comprises one or more switch devices and a spring assembly connected thereto.

In certain aspects, the one or more switch devices comprises at least one of a diode, a bipolar transistor, a bipolar junction transistor (BJT), or a field effect transistor (FET).

In certain aspects, the diode is a Schottky barrier diode (SBD) or a junction barrier Schottky (JBS) diode, and the FET is a metal-oxide-semiconductor field-effect transistor. (MOSFET), a metal-semiconductor field-effect transistor (MESFET), or a junction FET (JFET).

In certain aspects, one or more switch cells among the plurality of switch cells comprise a plurality of silicon-carbide FETs.

In certain aspects, the spring assembly comprises a monolithic spring or one or more disc springs. In certain aspects, the monolithic spring comprises a metal block with interleaved slits.

In certain aspects, at least one switch cell among the plurality of switch cells is arranged in a normal or an upside-down posture relative to another switch cell among the plurality of switch cells.

In certain aspects, the different switch position topologies comprise a first switch position topology, a second switch position topology, a third switch position topology, a fourth switch position topology, and a fifth switch position topology. The first switch position topology comprises a FET and a clamp. The second switch position topology comprises two FETs and a clamp, with the two FETs connected in series and disposed on both sides of the respective clamp. The third switch position topology comprises two FETs and a clamp, with the two FETs connected in a back-to-back arrangement and disposed on both sides of the respective clamp. The fourth switch position topology comprises a diode and a clamp. The fifth switch position topology comprises two diodes and a clamp, with the two diodes connected in series and disposed on both sides of the respective clamp

According to an embodiment, a converter module is provided that includes a first power module and a second power module, wherein each of the first and second power modules includes a plurality of switch cells having one or more different switch position topologies, a plurality of spaces, each space of the plurality of spaces located between two adjacent switch cells among the plurality of switch cells, a plurality of first electrodes, each first electrode of the plurality of first electrodes connected to a top surface of a particular switch cell among the plurality of switch cells, a plurality of second electrodes, each second electrode of the plurality of second electrodes connected to a bottom surface of a particular switch cell among the plurality of switch cells, and a control circuit electrically connected to the plurality of switch cells. In certain aspects, the converter includes one or more busbars to form electrical connections between the switch cells in the respective power module of the first and second power modules, and one or more decoupling capacitor assemblies accommodated by one or more spaces among the plurality of spaces in a respective power module of the first and second power modules.

In certain aspects, the first power module is stacked with the second power module such that one or more first electrodes in the first power module are electrically coupled to one or more second electrodes in the second power module.

In certain aspects, the converter module further includes a first direct current (DC) node, a second DC node, and a switching node having a voltage potential that is varying or jumping, wherein each of the first DC node and the second DC node is coupled to one or more second electrodes among the plurality of second electrodes in the first power module, and wherein the switching node is coupled to one or more first electrodes among the plurality of first electrodes in the second power module.

In certain aspects, one or more switch cells among the plurality of switch cells in the first power module form a first power loop, and wherein one or more switch cells among the plurality of switch cells in the first power module and one or more switch cells among the plurality of switch cells in the second power module form a second power loop.

In certain aspects, each switch cell among the plurality of switch cells in the first power module and the plurality of switch cells in the second module includes a plurality of parallel paths, and each path among the plurality of parallel paths in a respective switch cell includes one or more switch devices and a spring assembly connected thereto.

In certain aspects, the one or more switch devices comprises at least one of a diode, a bipolar transistor, a bipolar junction transistor (BJT), or a field effect transistor (FET).

In certain aspects, the diode is a Schottky barrier diode (SBD) or a junction barrier Schottky (JBS) diode, and the FET is a metal-oxide-semiconductor field-effect transistor. (MOSFET), a metal-semiconductor field-effect transistor (MESFET), or a junction FET (JFET).

In certain aspects, one or more switch cells among the plurality of switch cells in the first power module and the plurality of switch cells in the second power module include a plurality of silicon-carbide FETs.

In certain aspects, the spring assembly comprises a monolithic spring or one or more disc springs. In certain aspects, the monolithic spring comprises a metal block with interleaved slits.

In certain aspects, at least one of a busbar, a heatsink, or an insulator is disposed between the first power module and the second power module.

### BRIEF DESCRIPTION OF THE DRAWINGS

FIG. 1A is an exemplary circuit diagram of a conventional three-level (3L) neutral point clamped (NPC) converter structure.

FIG. 1B illustrates an exemplary circuit diagram of a 3L-NPC converter structure, in accordance with one or more embodiments of the present disclosure.

FIG. 1C shows examples of switch position topologies in a High-frequency press-pack (HFPP) module, in accordance with one or more embodiments of the present disclosure.

FIG. 2 is a block diagram of an exemplary vision system, in accordance with one or more exemplary embodiments of the present disclosure.

FIGS. 3A and 3B illustrate exemplary three-dimensional (3D) layout alternatives for a 3L-NPC topology, in accordance with one or more embodiments.

FIG. 4 is a top view of an exemplary layout of an HFPP switch cell, in accordance with one or more embodiments of the present disclosure.

FIG. 5A shows an exemplary double-sided sintered cell sample, in accordance with an embodiment of the present disclosure.

FIG. 5B shows an exemplary measurement setup for four-wire electrical resistance measurement.

FIG. 5C demonstrates an exemplary process for two-step double-sided sintering to fabricate a cell sample as shown in FIG. 5A, in accordance with an embodiment of the present disclosure.

FIG. 5D shows shear test results for a cell sample, in accordance with one embodiment of the present disclosure.

FIG. 6 is an example of a power module, in accordance with an embodiment of the present disclosure.

### DESCRIPTION

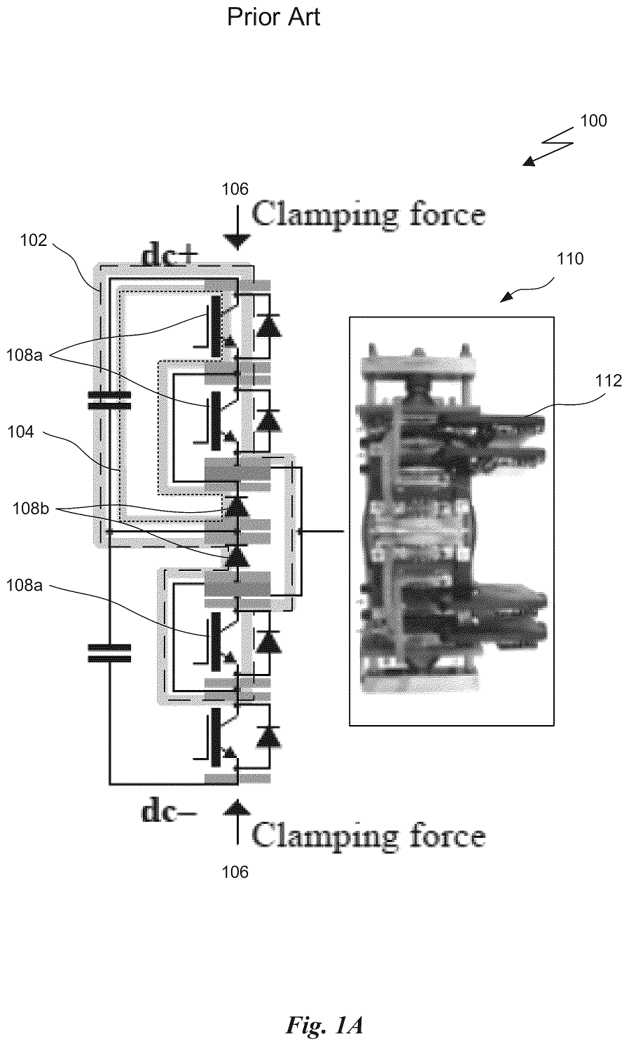

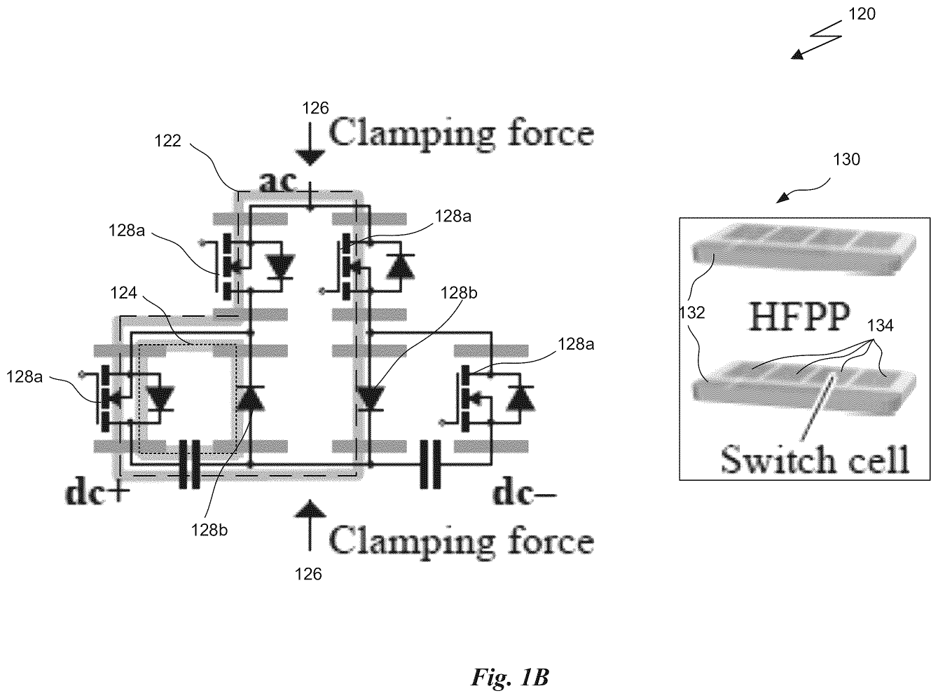

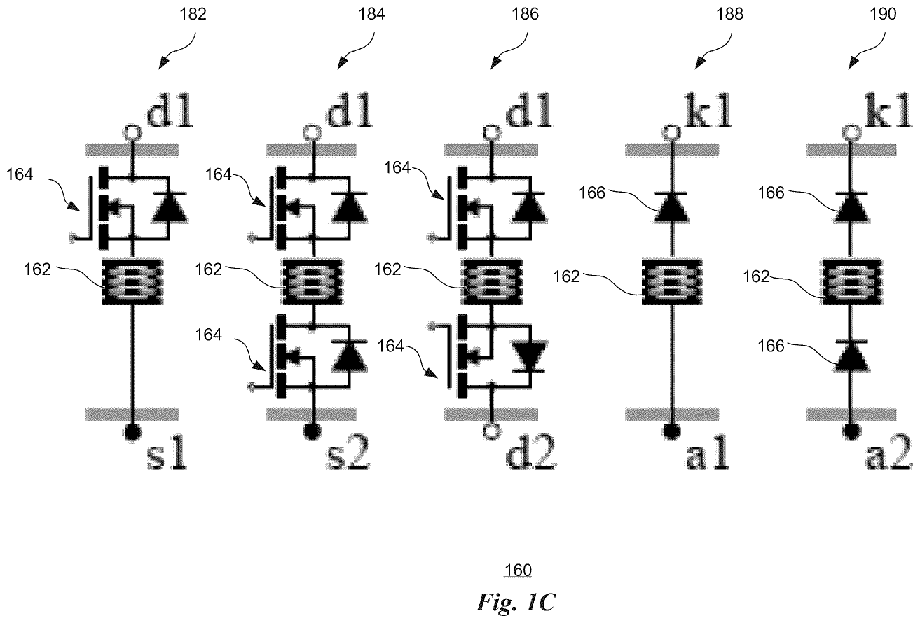

FIG. 1A is an exemplary circuit diagram of a conventional three-level (3L) neutral point clamped (NPC) converter structure 100. Box 110 provides an example of press-pack (PP) insulated-gate bipolar transistor (IGBT) modules 112.

As shown in FIG. 1A, the 3L-NPC converter structure 100 stacks PP IGBT modules (e.g., the modules 112) from “dc+” to “dc−”. The clamping force applied to the converter structure 100 is indicated by arrows 106. Two critical power loops are indicated by dashed lines 102 and 104, respectively. In this example, the power loop 102 passes through four switch cells (e.g., IGBTs 108a and diode 108b), while the power loop 104 passes through two switch cells (e.g., IGBT 108a and diode 108b). The switch cells (108a, 108b) in the converter structure 100 are included in different IGBT modules as shown in the product presented in the box 110. As such, the power loops 102 and 104 of the 3L-NPC converter structure 100 in such a design route through many modules (layers), which typically results in a power-loop inductance greater than 100 nanohenries (nH) concerning the small power loop (e.g., the dashed line 104) and the large power loop (e.g., the dashed line 102, the worst case).

FIG. 1B illustrates an exemplary circuit diagram of a 3L-NPC converter structure 120, in accordance with one or more embodiments of the present disclosure. As shown in box 130, the converter structure 120 may be formed using high-frequency press-pack (HFPP) modules (e.g., modules 132 with switch cells 134) with the modules stacked from “dc” to “ac.” Each HFPP module 132 denotes one layer of the stack and includes multiple switch cells 134.

In this example, each switch cell may include a MOSFET device 128a and/or a diode 128b. Alternatively, each switch cell may include a plurality of MOSFET devices 128a and/or diodes 128b connected in parallel, with each path having an identical arrangement. As shown in FIG. 1B, the first module layer (e.g., the bottom row) of the 3L-NPC converter structure 120 includes four switch cells (MOSFET devices 128a and diodes 128b), while the second module layer (e.g., the top row) includes two switch cells (MOSFET devices 128a). Two power loops (indicated by dashed lines 122 and 124, respectively) may be formed in the 3L-NPC converter structure 120. The clamping force applied to the converter structure 120 is indicated by arrows 126.

This novel stacking concept advantageously confines the power loops (e.g., 122, 124) within one or at most two modules to minimize power-loop inductance. Moreover, thinner module thickness further leads to lower inductance and higher power density. For example, the 3L-NPC converter structure 120 may achieve a power-loop inductance less than 10 nH. With that, HFPP modules 132 can operate with medium voltage (MV), high currents, fast switching transients, and high frequencies at the same time, even for sophisticated power loops in a variety of multilevel topologies.

Furthermore, the switch cells may be of any switch position topology. FIG. 1C shows examples 160 of multiple different switch position topologies (182, 184, 186, 188, and 190) in an HFPP module, in accordance with one or more embodiments of the present disclosure. The HFPP module may be a module presented in the box 130 in FIG. 1B. The switch position topology 182 includes a MOSFET device 164 and a clamp 162. The switch position topology 184 includes two MOSFET devices 164 and a clamp 162, with the two MOSFET devices 164 connected in series and disposed on both sides of the clamp 162. The switch position topology 186 includes two MOSFET devices 164 and a clamp 162 with the two MOSFET devices 164 connected in a back-to-back arrangement and disposed on both sides of the clamp 162. The switch position topology 188 includes a diode 166 and a clamp 162. The switch position topology 190 includes two diodes 166 and a clamp 162, with the two diodes 166 connected in series and disposed on both sides of the clamp 162. It will be noted that other suitable switch position topologies may be utilized with various arrangements, and/or other types of switch devices. For example, the switch devices may include at least one of a diode, a bipolar transistor, a bipolar junction transistor (BJT), or a field effect transistor (FET). The diodes may be of various types, including Schottky barrier diodes (SBDs), junction barrier Schottky (JBS) diodes, and more. The transistors may also be of various types, including metal-oxide-semiconductor field-effect transistors (MOSFETs), metal-semiconductor field-effect transistors (MESFETs), insulated-gate bipolar transistors (IGBTs), junction transistors (JFETs), and more.

In the examples provided herein, unfilled circles denote the positive voltage blocking terminal; filled circles denote the negative blocking terminal; and two unfilled circles denote bidirectional blocking terminal.

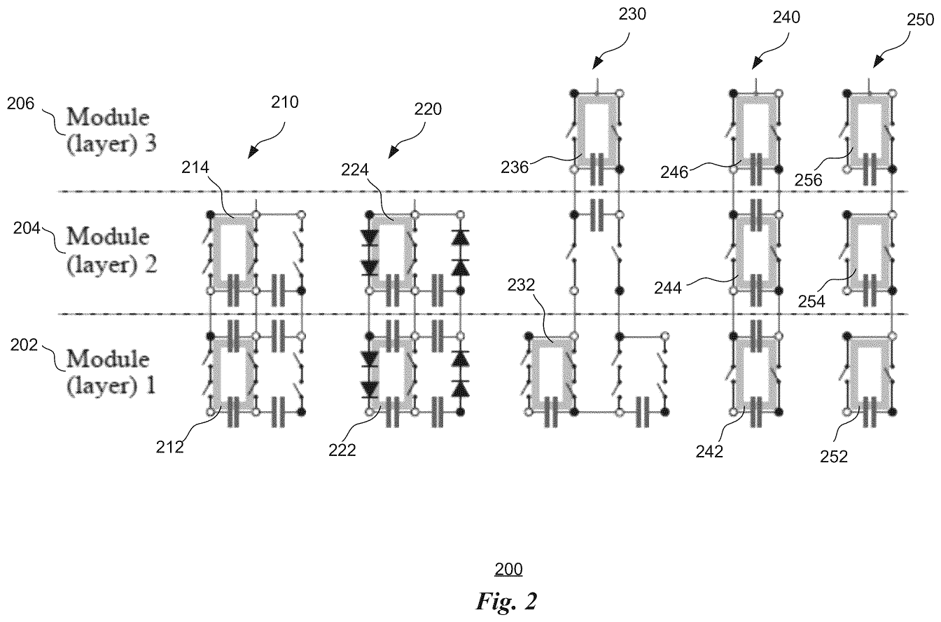

Using five-level (5L) multilevel inverters as an example, the clamping structures as provided in the present disclosure (e.g., as shown in FIG. 1C) can be used for various topologies (e.g., the exemplary inverters as illustrated in FIG. 2), where the power-loop inductances in all cases are reduced or minimized, e.g., to less than 10 nH. Furthermore, the switch cell number or layout on different module layers may also advantageously vary (e.g., be designed differently) for various converter applications. For instance, as shown in FIG. 1B, the first module layer (e.g., the bottom row) of the 3L-NPC converter 120 requires four switch cells, and the second layer (e.g., the top row) needs a minimum of two.

FIG. 2 is an example 200 illustrating multiple different exemplary topologies for five-level multilevel inverters (210, 220, 230, 240, 250), in accordance with one or more embodiments of the present disclosure. These topologies correspond to one phase of the corresponding inverters (210, 220, 230, 240, 250). HFPP SiC modules may be employed in these topologies. As shown in FIG. 2, the topologies each may include multiple modules (e.g., 202, 204, and/or 206) corresponding to different layers (e.g., layer 1, layer 2, and/or layer 3, respectively). Each module may include a number of switch cells of various topologies, such as the exemplary topologies (182, 184, 186, 188, 190) as shown in FIG. 1C.

Referring to FIG. 2, the inverter 210 is a 5L symmetrical multilevel converter (5L-SMC), with six switch cells packed in two modules 202 and 204. In this example, the modules 202 and 204 each includes three switch cells. Each switch cell includes a pair of switches connected in series or back-to-back, which may resemble the topology 184 or 186 in FIG. 1C. At the corresponding phase as illustrated in FIG. 2, two power loops 212 and 214 are established in the respective modules 202 and 204.

The inverter 220 is a 5L-Vienna-type-SMC, with six switch cells packed in two modules 202 and 204. In this example, the modules 202 and 204 each includes three switch cells. Each switch cell includes a pair of switches connected in series or back-to-back or a pair of diodes, which may resemble the topology 184, 186, or 190 in FIG. 1C. At the corresponding phase as illustrated in FIG. 2, two power loops 222 and 224 are established in the respective modules 202 and 204.

The inverter 230 is a 5L active neutral-point clamped (5L-ANPC) inverter, with eight switch cells packed in three modules 202, 204, and 206. In this example, the module 202 includes four switch cells, the module 204 includes two switch cells, and the module 206 includes two switch cells. Each switch cell includes a single switch or a pair of switches connected in series, which may resemble the topology 182 or 184 in FIG. 1C. At the corresponding phase as illustrated in FIG. 2, two power loops 232 and 236 are established in the respective modules 202 and 206.

The inverter 240 is a 5L flying capacitor (5L-FC), with six switch cells packed in three modules 202, 204, and 206. In this example, the modules 202, 204, and 206 each includes two switch cells. Each switch cell includes a single switch, which may resemble the topology 182 in FIG. 1C. At the corresponding phase as illustrated in FIG. 2, three power loops 242, 244, and 246 are established in the respective modules 202, 204, and 206.

The inverter 250 is a 5L modular multilevel converter (5L-MMC), with six switch cells packed in three modules 202, 204, and 206. In this example, the modules 202, 204, and 206 each includes two switch cells. Each switch cell includes a single switch, which may resemble the topology 182 in FIG. 1C. At the corresponding phase as illustrated in FIG. 2, three power loops 252, 254, and 256 are established in the respective modules 202, 204, and 206.

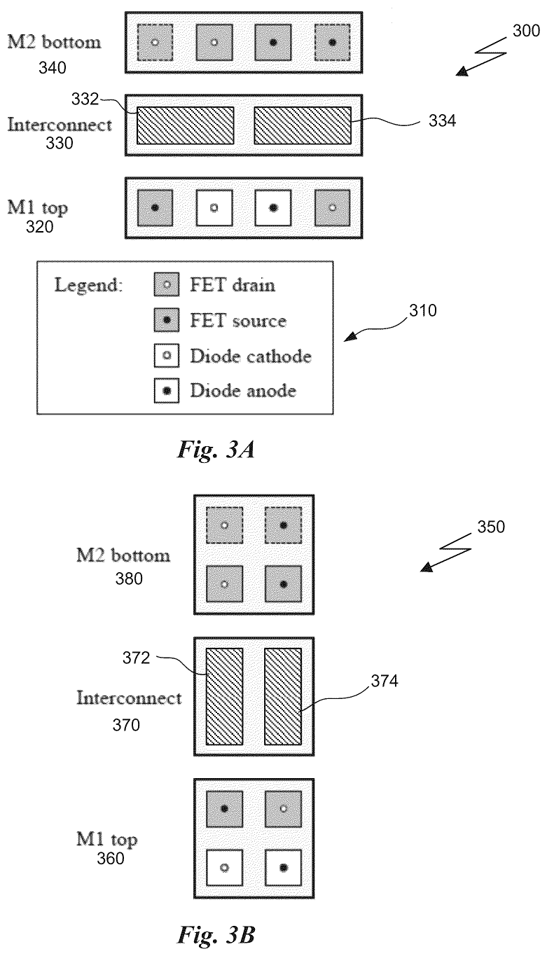

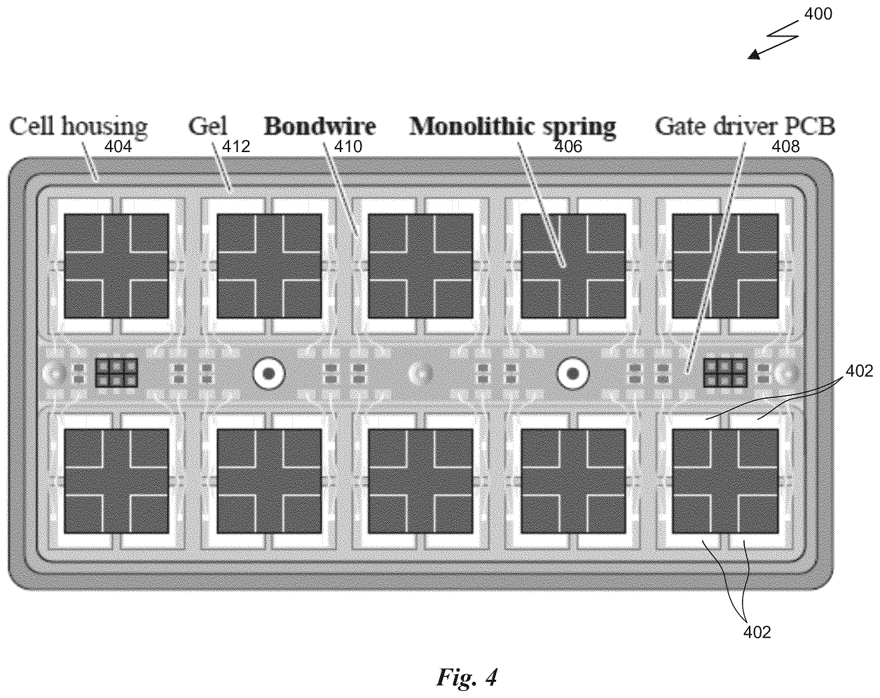

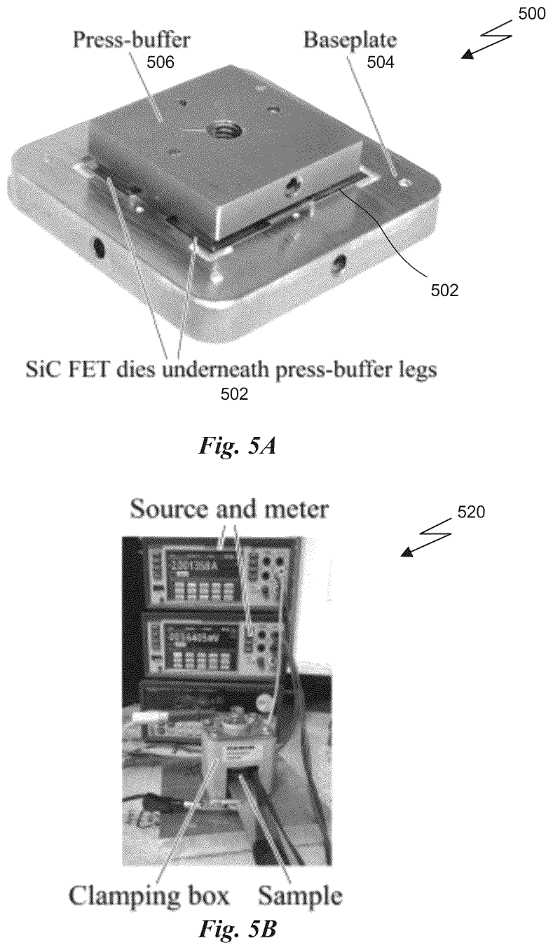

FIGS. 3A and 3B illustrate exemplary three-dimensional (3D) layout alternatives for a 3L-NPC topology, in accordance with one or more embodiments. The 3L-NPC topology may be employed based on the circuit diagram of the 3L-NPC converter structure 120 as shown in FIG. 1B.

The 3D layout implementations (300, 350) in FIGS. 3A and 3B correspond to the layout design of interconnect layers in integrated circuit (IC) fabrication, which are designed to connect two modules, Module 1 and Module 2 (M1 and M2, respectively). The modules (M1, M2) each includes four switch cells, each switch cell may include one or more switch devices (e.g., FETs) and/or diodes. The legend 310 in FIG. 3A shows symbols representing contact regions associated with the corresponding terminals of FETs/diodes as illustrated in FIGS. 3A and 3B. Unfilled circles denote the positive voltage blocking terminal; filled circles denote the negative blocking terminal.

Referring to FIG. 3A, both M1 and M2 are designed with 1×4 cells. Alternatively, M2 may be designed with 1×2 or 1×4 cells depending on whether the high conduction loss of the M2 FETs in the corresponding 3L-NPC converter needs to be reduced in parallel. In this example, M1 and M2 are stacked vertically, where the contacts (e.g., electrodes) in the M1 top interconnect layer 320 are electrically connected to the contacts in the M2 bottom interconnect layer 340 through the connections defined by the interconnect layer 330, such as the patterns 332 and 334.

Referring to FIG. 3B, both M1 and M2 are designed with 2×2 cells. M1 and M2 are stacked vertically, where the contacts in the M1 top interconnect layer 360 are electrically connected to the contacts in the M2 bottom interconnect layer 380 through the connections defined by the interconnect layer 370, such as the patterns 372 and 374. The 2×2 design in FIG. 3B can achieve the same small-loop inductance as illustrated in FIG. 1B but with mitigated large-loop inductance compared to FIG. 3A.

FIG. 4 is a top view of an exemplary layout of an HFPP switch cell 400, in accordance with one or more embodiments of the present disclosure. The HFPP switch cell 400 includes ten groups of SiC FET dies 402, with each group containing 2×2 SiC FET dies 402. The groups of SiC FET dies 402 are situated in a cell housing 404. Each group of SiC FET dies 402 are connected to a spring (e.g., the monolithic spring (MS) 406). The SiC FET dies 402 are electrically connected to contacts defined on a control circuit (e.g., an embedded gate driver printed circuit board (PCB) 408) through suitable connections (e.g., bondwire 410). The HFPP switch cell 400 may be encapsulated by a gel layer 412 to protect the components therein.

The HFPP switch cell 400 may be designed similar to a direct bond copper (DBC)-free flat-pack power module to minimize manufacturing costs. Hybrid interconnections are implemented for gate pads and source pads of the SiC FETs. In this example, every four source pads as a group are sintered to the four legs of a MS 406. Wire-bonding (e.g., bondwire 410) is used for gate and/or Kelvin-source interconnections to the embedded gate driver PCB 408 at the center of the switch cell 400. This arrangement ensures that the gate pad joints are not subjected to high-current stresses. The gate driver PCB 408 may include many totem-pole current boosters, gate resistance, and low-voltage decoupling capacitors to provide sufficient driving currents and minimized gate-loop inductance. Examples of MSs useful in the HFPP designs according to embodiments may be found in provisional application No. 63/496,759, titled “Monolithic Spring Assemblies for High-Frequency Press-Pack Modules”, and filed concurrently with the provisional application No. 63/496,779 on Apr. 18, 2023, which is incorporated by reference in its entirety. As disclosed therein, in certain aspects, the body of the MS may include beryllium copper (BeCu) and the lid and/or baseplate for source and gate connections may include copper-diamond (CuDmd). Other useful materials for the body and other useful materials for the baseplate and lid as would be apparent to one skilled in the art may be used.

Without considering gate drivers at this point, the cell PP approach breaks into three main categories—design and optimization of the main components (e.g., baseplate, press-buffer, and MS), switch cell sample fabrication, and its characterization and validation. In some embodiments, SiC junction FET (JFET) mechanical dies with electroless nickel immersion gold (ENIG) metallization on the source pads may be utilized for the cell PP implementation. SiC junction FETs are normally-on devices and behave simply as a resistor without gate drivers.

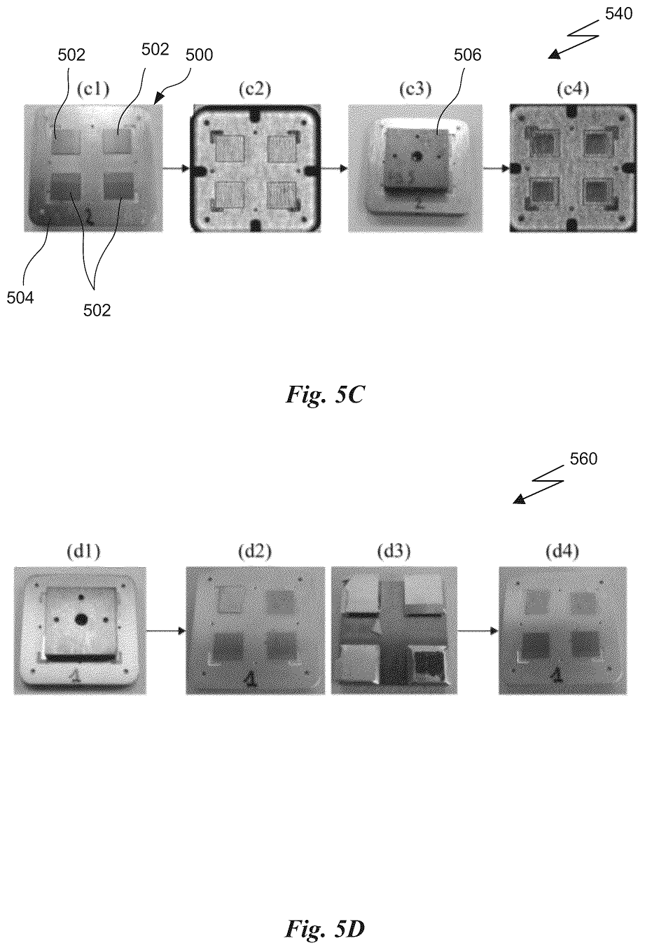

FIG. 5A shows an exemplary double-sided sintered cell sample 500, in accordance with an embodiment of the present disclosure. In this example, four dies (e.g., dies 502) are sintered to a baseplate 504 first, followed by a second sintering step to bond together the four legs of a press-buffer 506 and four source pads. Sintered cell samples (e.g., the sintered cell 500) will then pass through scanning acoustic microscopy (SAM), electrical/thermal resistance, and shear strength tests. FIG. 5B shows an exemplary measurement setup 520 for four-wire electrical resistance measurement. In this example setup, the clamp box is WestCode CMK1-500B34M, and the load cell is Omega LCM307-50KN.

FIG. 5C demonstrates an exemplary process 540 for two-step double-sided sintering to fabricate a cell sample 500 as shown in FIG. 5A, in accordance with an embodiment of the present disclosure. In the first step, a group of dies 502 are sintered to a baseplate 504. Photograph (c1) shows the sample 500 before the sintering, while SAM image (c2) shows the sample 500 after the sintering. In the second step, the group of dies 502 are sintered to a press-buffer 506. Photograph (c3) shows the sample 500 before the sintering, while SAM image (c4) shows the sample 500 after the sintering. Double-sided sintering was conducted to fabricate three cell samples (Samples 1, 2, and 3) based on Qorvo 1.2 kV, 7.6 mΩ UF3N120008Z dies under 15 Megapascal (MPa), 250° C., and 180 seconds. Visual inspection and scanning acoustic microscope (SAM) test after each sintering step have verified the good quality of sintering. The de resistance of the samples was measured by a four-wire method in a clamp box (as shown in FIG. 5B) with a miniature compression load cell inserted for clamping force measurement. It is noted that the total resistance includes half of the baseplate and press-buffer body resistance and four parallel die resistance along with their bonding resistance at both sides. The obtained results of dc resistance were Rsmp2=1.847 mΩ and Rsmp3=1.818 mΩ for Samples 2 and 3, respectively, where “mΩ” stands for milliohm. The de resistance results for Samples 2 and 3 showed no observed dependency on the clamping force, indicating a solid bonding outcome. These results are within reasonable tolerance of the datasheet value of four parallel 7.5 mΩ dies at a gate-to-source voltage Vgs=0 V, a drain current Id=2 A, and a junction temperature Tj=25° C. Subsequently, a shear strength test was performed on Sample 1. FIG. 5D shows shear test results (d1-d4) 560 for a cell sample, in accordance with one embodiment of the present disclosure. The cell sample in this example is Sample 1. Photographs (d1-d4) exhibit satisfactory results from the shear strength test. The first crack occurred at 1,082 Newtons where the shear force was applied to the press-buffer. Three dies were still attached to the press-buffer, but one die stayed with the baseplate. The total die area attached to the baseplate is about 142.9 square millimeters (or 0.2215 square inches), satisfying MIL-STD-883 that requires a minimum of 5 kilograms (50.86 Newtons). The second crack occurred with the shear force value on the remaining dies being 664 Newtons.

Embodiments herein advantageously enable boosting grid resilience disruptively, and achieving (i) real grid-scale ratings (e.g., 3.3 kV, 1 kA nominal, and 5 kA peak); (ii) ultrafast switching transients (e.g., 250 V/ns and 100 A/ns) and frequencies (e.g., 40 kHz@1 kA); (iii) voltage overshoots <500 volts and RR current overshoots <200 amperes under 100 A/ns; (iv) total electromagnetic interference (EMI) coupling capacitance Ccp<0.1 picofarad (noise current <25 mA under 250 V/ns); (v) minimized coefficient of thermal expansion (CTE) mismatch and enhanced HF conductive areas for 40 kHz switch currents; (vi) partial-discharge inception voltage (PDIV)>5 kV and reliable SCFM; and (vii) utmost flexibility, scalability, manufacturability, and maintainability for a variety of multilevel topologies. Such striking performance can be attained by the (1) novel package-level switch-cell building block (SCBB) and rotated stacking concepts to minimize Ls beyond topological limits; (2) novel Beryllium-Copper (BeCu) monolithic springs (MSs) for clamping force realization and Cu-Diamond (CuDmd) composite to reduce high-frequency (HF) electrical resistance and enhance thermal conductivity and near-die thermal capacitance; (3) novel SBD-embedded SiC MOSFET die technologies with negligible internal gate resistance, along with extensively distributed gate current boosters (GCBs) that minimize gate-loop inductance (Lg); and/or (4) contactless (>20 mm) switch-cell (SC) actuation for EM1 mitigation and high maintainability.

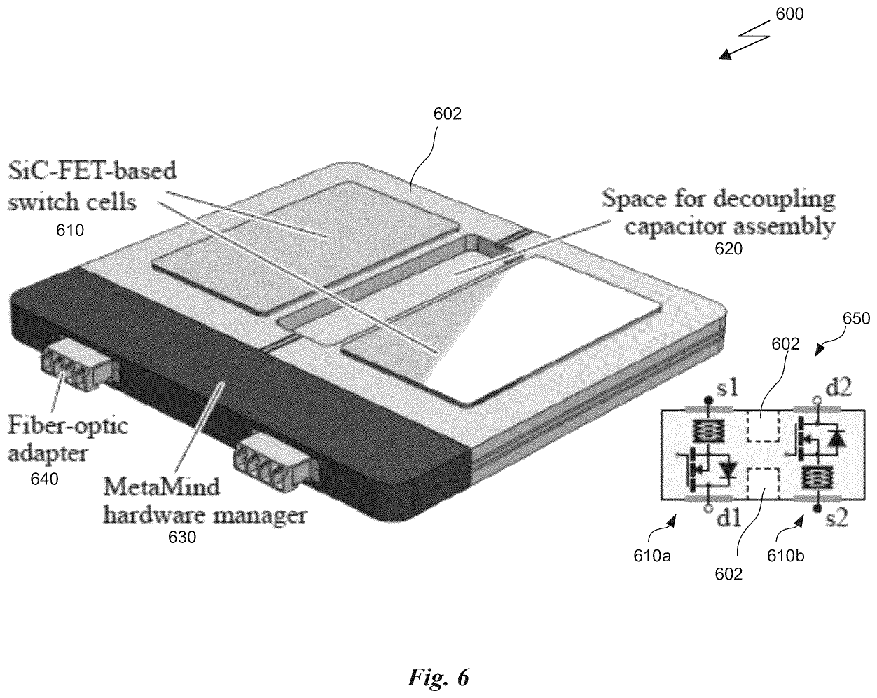

FIG. 6 is an example of a power module 600, in accordance with an embodiment of the present disclosure. The power module 600 includes two SiC-FET-based switch cells 610 situated in a housing 602, a space 620 between the switch cells 610, and a controller circuit 630, and adapters 640. An equivalent circuit is provided as circuit 650.

The SiC-FET-based switch cells 610 may include any of the switch cells provided in the present disclosure, such as the exemplary implementations discussed with reference to FIGS. 1-5. The space 620 may be utilized to accommodate one or more decoupling capacitor assemblies. The space 620 may be created on the top surface and/or bottom surface of the housing 602. The controller circuit 630 may include a MetaMind hardware manager, which is configured to control the operation of the switch cells 610. The adapters 640 may be Fiber-Optic adapters, enabling connection to external devices.

As shown in the equivalent circuit 650, the power module 600 includes switch cells 610a and 610b with different topologies. One or more spaces 620 may be implemented on either or both sides of the power module 600.

As the foregoing illustrates, the devices, systems and methods according to the present embodiments provide novel modularity and stacking arrangements of high-frequency press-pack (HFPP) cells for low power-loop inductance.

In one embodiment, a power module may comprise a plurality of switch cells having one or more different switch position topologies (e.g., as shown in FIG. 1C). The power module may comprise one or more spaces, with each space located between two adjacent switch cells among the plurality of switch cells. The plurality of spaces are configured to accommodate one or more decoupling capacitor assemblies. The power module may comprise a plurality of first electrodes (e.g., in M1 top layer 320 as shown in FIG. 3A), a plurality of second electrodes (e.g., in M2 bottom layer 340 as shown in FIG. 3A), and a control circuit (e.g., the gate driver PCB 408 as shown in FIG. 4 and/or the controller circuit 630 as shown in FIG. 6) electrically connected to the plurality of switch cells. Each first electrode may be connected to a top surface of a particular switch cell among the plurality of switch cells. Each second electrode may be connected to a bottom surface of a particular switch cell among the plurality of switch cells.

In one embodiment, the different switch position topologies may include examples as shown in FIG. 1C, as well as other suitable arrangements, and/or with other types of switch devices. For example, as shown in FIG. 1C, a switch position topology 182 may include a MOSFET device 164 and a clamp 162. A switch position topology 184 may include two MOSFET devices 164 and a clamp 162, with the two MOSFET devices 164 connected in series and disposed on both sides of the clamp 162. A switch position topology 186 may include two MOSFET devices 164 and a clamp 162 with the two MOSFET devices 164 connected in a back-to-back arrangement and disposed on both sides of the clamp 162. A switch position topology 188 may include a diode 166 and a clamp 162. A switch position topology 190 may include two diodes 166 and a clamp 162, with the two diodes 166 connected in series and disposed on both sides of the clamp 162. In further embodiments, the switch devices may include at least one of a diode, a bipolar transistor, a bipolar junction transistor (BJT), or a field effect transistor (FET). The diodes may be of various types, including Schottky barrier diodes (SBDs), junction barrier Schottky (JBS) diodes, and more. Additionally and/or alternatively, the transistors may be of various types, including metal-oxide-semiconductor field-effect transistors (MOSFETs), metal-semiconductor field-effect transistors (MESFETs), insulated-gate bipolar transistors (IGBTs), junction transistors (JFETs), and more.

In one embodiment, each switch cell among the plurality of switch cells may comprise a plurality of parallel paths, and each path among the plurality of parallel paths in a respective switch cell may comprise one or more switch devices and a spring assembly connected thereto.

In one embodiment, one or more switch cells among the plurality of switch cells may comprise a plurality of silicon-carbide (SIC) FETs.

In one embodiment, the spring assembly may comprise a monolithic spring.

In one embodiment, the monolithic spring may comprise a metal block with interleaved slits.

In one embodiment, one switch cell among the plurality of switch cells may be arranged in an upside-down posture relative to another switch cell among the plurality of switch cells. However, it will be noted that other arrangement may be adopted. For example,

In one embodiment, a converter module may comprise two or more power modules of any topology. For example, the converter module may comprise a first power module and a second power module. Each of the first and second power modules may comprise a plurality of switch cells having one or more different switch position topologies, one or more spaces with each space located between two adjacent switch cells among the plurality of switch cells, a plurality of first electrodes, a plurality of second electrodes, and a control circuit electrically connected to the plurality of switch cells. Each first electrode may be connected to a top surface of a particular switch cell among the plurality of switch cells. Each second electrode may be connected to a bottom surface of a particular switch cell among the plurality of switch cells. The converter module may comprise one or more busbars (e.g., in the control circuit 630 as shown in FIG. 6) to form electrical connections between the switch cells in the respective power module of the first and second power modules. One or more decoupling capacitor assemblies may be situated in one or more spaces in a respective power module of the first and second power modules.

In one embodiment, the first power module may be stacked with the second power module such that one or more first electrodes in the first power module are electrically coupled to one or more second electrodes in the second power module.

In one embodiment, the converter module may further comprise a first direct current (DC) node, a second DC node, and a switching node whose voltage potential is jumping or varying. For example, the converter module may be a 3L-NPC converter structure 120 as shown in FIG. 1B. Each of the first DC node and the second DC node may be coupled to one or more second electrodes among the plurality of second electrodes in the first power module. The switching node may be coupled to one or more first electrodes among the plurality of first electrodes in the second power module.

In one embodiment, one or more switch cells among the plurality of switch cells in the first power module may form a first power loop. One or more switch cells among the plurality of switch cells in the first power module and one or more switch cells among the plurality of switch cells in the second power module may form a second power loop.

In one embodiment, each switch cell among the plurality of switch cells in the first power module and the plurality of switch cells in the second module may comprise a plurality of parallel paths, and each path among the plurality of parallel paths in a respective switch cell may comprise one or more switch devices and a spring assembly connected thereto.

In further embodiments, the switch devices may include at least one of a diode, a bipolar transistor, a bipolar junction transistor (BJT), or a field effect transistor (FET). The diodes may be of various types, including Schottky barrier diodes (SBDs), junction barrier Schottky (JBS) diodes, and more. Additionally and/or alternatively, the transistors may be of various types, including metal-oxide-semiconductor field-effect transistors (MOSFETs), metal-semiconductor field-effect transistors (MESFETs), insulated-gate bipolar transistors (IGBTs), junction transistors (JFETs), and more.

In one embodiment, one or more switch cells among the plurality of switch cells in the first power module and the plurality of switch cells in the second power module may comprise a plurality of SiC FETs.

In one embodiment, the spring assembly may comprise a monolithic spring.

In one embodiment, the monolithic spring may comprise a metal block with interleaved slits.

In one embodiment, at least one of a busbar, a heatsink, or an insulator is disposed between the first power module and the second power module.

It will be noted that the converter module may include two or more power modules with any suitable arrangements. For example, each power module may include two or more switch cells, with each cell of any topology. The switch cells may be arranged in any polarity, such as normal polarity or upside-down polarity.

U.S. patent application Ser. No. 18/175,980, filed Feb. 28, 2023, titled POWER MODULES FOR CIRCUIT PROTECTION, and U.S. Provisional Patent Application No. 63/315,195, filed Mar. 1, 2022, titled PASSIVELY COOLED ULTRA-EFFICIENT AND RELIABLE INTELLIGENT POWER MODULE FOR MVDC SOLID-STATE CIRCUIT BREAKERS, both disclose additional aspects of power modules, including switch cell components and switch cell modules, useful in embodiments herein, and are both incorporated by reference herein for all purposes.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the disclosed subject matter (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or example language (e.g., “such as”) provided herein, is intended merely to better illuminate the disclosed subject matter and does not pose a limitation on the scope of the invention unless otherwise claimed. No language in the specification should be construed as indicating any non-claimed element as essential to the practice of the invention.

Certain embodiments are described herein. Variations of those embodiments may become apparent to those of ordinary skill in the art upon reading the foregoing description. The inventors expect skilled artisans to employ such variations as appropriate, and the inventors intend for the embodiments to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

What is claimed is:

1. A power module, comprising:
a plurality of switch cells having one or more different switch position topologies;
a plurality of spaces, each space located between two adjacent switch cells among the plurality of switch cells, wherein the plurality of spaces are configured to accommodate one or more decoupling capacitor assemblies;
a plurality of first electrodes, each first electrode connected to a top surface of a particular switch cell among the plurality of switch cells;
a plurality of second electrodes, each second electrode connected to a bottom surface of a particular switch cell among the plurality of switch cells; and
a control circuit electrically connected to the plurality of switch cells.

2. The power module according to claim 1, wherein each switch cell among the plurality of switch cells comprises a plurality of parallel paths, and each path among the plurality of parallel paths in a respective switch cell comprises one or more switch devices and a spring assembly connected thereto.

3. The power module according to claim 2, wherein the one or more switch devices comprise at least one of a diode, a bipolar transistor, a bipolar junction transistor (BJT), an insulated-gate bipolar transistor (IGBT), or a field effect transistor (FET).

4. The power module according to claim 3, wherein the diode is a Schottky barrier diode (SBD) or a junction barrier Schottky (JBS) diode, and wherein the FET is a metal-oxide-semiconductor field-effect transistor (MOSFET), a metal-semiconductor field-effect transistor (MESFET), or a junction FET (JFET).

5. The power module according to claim 2, wherein one or more switch cells among the plurality of switch cells comprise a plurality of silicon-carbide FETs.

6. The power module according to claim 2, wherein the spring assembly comprises a monolithic spring.

7. The power module according to claim 6, wherein the monolithic spring comprises a metal block with interleaved slits.

8. The power module according to claim 1, wherein one switch cell among the plurality of switch cells is arranged in a normal or an upside-down posture relative to another switch cell among the plurality of switch cells.

9. The power module according to claim 1, wherein the different switch position topologies comprise a first switch position topology, a second switch position topology, a third switch position topology, a fourth switch position topology, and a fifth switch position topology, wherein the first switch position topology comprises a FET and a clamp, wherein the second switch position topology comprises two FETs and a clamp, with the two FETs connected in series and disposed on both sides of the respective clamp, wherein the third switch position topology comprises two FETs and a clamp, with the two FETs connected in a back-to-back arrangement and disposed on both sides of the respective clamp, wherein the fourth switch position topology comprises a diode and a clamp, and the fifth switch position topology comprises two diodes and a clamp, with the two diodes connected in series and disposed on both sides of the respective clamp.

10. A converter module, comprising:
a first power module and a second power module, wherein each of the first and second power modules comprises:
a plurality of switch cells having one or more different switch position topologies;
a plurality of spaces, each space located between two adjacent switch cells among the plurality of switch cells;
a plurality of first electrodes, each first electrode connected to a top surface of a particular switch cell among the plurality of switch cells;
a plurality of second electrodes, each second electrode connected to a bottom surface of a particular switch cell among the plurality of switch cells; and
a control circuit electrically connected to the plurality of switch cells; and
one or more busbars to form electrical connections between the switch cells in the respective power module of the first and second power modules; and
one or more decoupling capacitor assemblies accommodated by one or more spaces among the plurality of spaces in a respective power module of the first and second power modules.

11. The converter module according to claim 10, wherein the first power module is stacked with the second power module such that one or more first electrodes in the first power module are electrically coupled to one or more second electrodes in the second power module.

12. The converter module according to claim 11, further comprises:
a first direct current (DC) node;
a second DC node; and
a switching node whose voltage potential is jumping or varying,
wherein each of the first DC node and the second DC node is coupled to one or more second electrodes among the plurality of second electrodes in the first power module, and
wherein the switching node is coupled to one or more first electrodes among the plurality of first electrodes in the second power module.

13. The converter module according to claim 11, wherein one or more switch cells among the plurality of switch cells in the first power module form a first power loop, and wherein one or more switch cells among the plurality of switch cells in the first power module and one or more switch cells among the plurality of switch cells in the second power module form a second power loop.

14. The converter module according to claim 10, wherein each switch cell among the plurality of switch cells in the first power module and the plurality of switch cells in the second module comprises a plurality of parallel paths, and each path among the plurality of parallel paths in a respective switch cell comprises one or more switch devices and a spring assembly connected thereto.

15. The converter module according to claim 14, wherein the one or more switch devices comprises at least one of a diode, a bipolar transistor, an insulated-gate bipolar transistor (IGBT), a bipolar junction transistor (BJT), or a field effect transistor (FET).

16. The converter module according to claim 15, wherein the diode is a Schottky barrier diode (SBD) or a junction barrier Schottky (JBS) diode, and wherein the FET is a metal-oxide-semiconductor field-effect transistor (MOSFET), a metal-semiconductor field-effect transistor (MESFET), or a junction FET (JFET).

17. The converter module according to claim 14, wherein one or more switch cells among the plurality of switch cells in the first power module and the plurality of switch cells in the second power module comprise a plurality of silicon-carbide FETs.

18. The converter module according to claim 14, wherein the spring assembly comprises a monolithic spring.

19. The converter module according to claim 18, wherein the monolithic spring comprises a metal block with interleaved slits.

20. The converter module according to claim 10, wherein at least one of a busbar, a heatsink, or an insulator is disposed between the first power module and the second power module.
